(19) United States
(12) Patent Application Publication
(10) Pub. No.: US 2022/0310718 A1
(43) Pub. Date: Sep. 29, 2022

(54) FLEXIBLE DISPLAY SUITABLE FOR UNDER-DISPLAY SENSOR

(71) Applicant: ArcSoft Corporation Limited, Hangzhou (CN)

(72) Inventor: Byung Il Min, Hangzhou (CN)

(73) Assignee: ArcSoft Corporation Limited, Hangzhou (CN)

(21) Appl. No.: 17/656,601

(22) Filed: Mar. 25, 2022

(30) Foreign Application Priority Data
Mar. 26, 2021 (CN) 202110326230.7

(51) Int. Cl. H01L 27/32; H01L 51/52

(52) U.S. Cl. CPC H01L 27/3234; H01L 51/5284; H01L 51/5293; H01L 51/5246; H01L 27/3244; H01L 2251/5338

(57) ABSTRACT

Embodiments disclosed herein relate to a flexible display suitable for an under-display sensor. The flexible display may include: a display layer including a thin film transistor driven by an applied electrical signal and a light emitting layer that generates light by means of the thin film transistor; a cover window including an optically clear flexible material to protect the display layer and laminated on the display layer; and a flexible lower layer arranged below the display layer to support and protect the display layer and having optical isotropy.

### BACKGROUND

Under-display sensors are not only suitable for portable electronic devices such as mobile phones or tablet computers, but also suitable for video electronic devices such as televisions or monitors. In recent years, an increasing number of displays have been designed that occupy almost the entire front surface of electronic devices. While the size of a display is increased in response to the need for a larger frame, at least a part of the front surface is secured to dispose a camera, in particular, to dispose an illuminance sensor. Proximity sensors using ultrasonic waves or the like can also be applied to such a structure in which the front surface is covered by a display, but it is difficult to integrate an illuminance sensing function. On the other hand, the illuminance sensor may be positioned in a region other than the front surface, but there may be a problem that surrounding light cannot be sensed in the presence of a shell for protecting the electronic device. Therefore, the most ideal position for arranging the illuminance sensor is the front surface of the electronic device, but it is difficult to secure a position for arranging the commonly used illuminance sensor in a design where the display occupies the entire front surface.

An under-display sensor detects the light passing through the display. Therefore, the transmittance of the display needs to be high. A thin film transistor (TFT), a color filter, a polarizing layer, etc. are formed on an optically clear or optically isotropic glass substrate in a rigid display. In contrast, in the case of various flexible displays such as foldable and rollable displays, in order to obtain flexibility, the lower part of the display includes an optically opaque or optically anisotropic layer. In particular, the birefringence of light generated by the anisotropic layer disables the under-display sensor which uses the properties of polarized light to operate.

### SUMMARY

Embodiments of the present invention provide a flexible display suitable for an under-display sensor.

According to an aspect, a flexible display suitable for an under-display sensor includes: a display layer comprising a thin film transistor driven by an applied electrical signal and a light emitting layer that generates light by means of the thin film transistor; a cover window including an optically clear flexible material to protect the display layer and laminated on the display layer; and a flexible lower layer arranged below the display layer to support and protect the display layer and having optical isotropy.

In one embodiment, the lower layer includes: a polyimide (PI) layer, on which the thin film transistor is formed; a base film arranged below the polyimide layer and having the optical isotropy and flexibility; and an optically clear adhesive component arranged between the polyimide layer and the base film.

In one embodiment, the base film is formed by any one selected from the group consisting of cellulose acetate propionate (CAP), ethylene vinylalcohol copolymer (EVOH), polyacrylate (PA), polyallylate (PAR), polycarbonate (PC), polyetherimide (PEI), polyethersulphone (PES), polyethylenenaphthalate (PEN), polyimide (PI), polymethylmethacrylate (PMMA), polyphenylene sulfide (PPS), polystyrene (PS), polyvinylidene chloride (PVDC), polyvinylidene difluoride (PVDF), styrene acrylonitrile (SAN), tri-acetyl cellulose (TAC), methylpentene (TPX), and combinations thereof.

In one embodiment, when viewed from above, a part of the base film is an optically isotropic region having the optical isotropy.

In one embodiment, the optically isotropic region is formed by any one selected from the group consisting of cellulose acetate propionate (CAP), ethylene vinylalcohol copolymer (EVOH), polyacrylate (PA), polyallylate (PAR), polycarbonate (PC), polyetherimide (PEI), polyethersulphone (PES), polyethylenenaphthalate (PEN), polyimide (PI), polymethylmethacrylate (PMMA), polyphenylene sulfide (PPS), polystyrene (PS), polyvinylidene chloride (PVDC), polyvinylidene difluoride (PVDF), styrene acrylonitrile (SAN), tri-acetyl cellulose (TAC), methylpentene (TPX), and combinations thereof.

In one embodiment, the remaining region of the base film is optically opaque or optically anisotropic when viewed from above.

In one embodiment, the remaining region is formed by any one selected from the group consisting of ethylene tetrafluoroethylene (ETFE), chlorotrifluoroethylene (CTFE), polyetherimide (PEI), polyethersulphone (PES), polyethyeleneterepthalate (PET), polyphenylenesulfide (PPS), poly(aryleneether sulfone), poly(tetrafluoroethylene) (PTFE), and combinations thereof.

In one embodiment, the base film further includes a light-shielding region. The light-shielding region is arranged between the optically isotropic region and the remaining region of the base film and extends from an upper surface of the base film to a lower surface of the base film.

In one embodiment, the optically isotropic region of the base film includes a plurality of through holes extending from the upper surface to the lower surface. The remaining region of the base film is optically opaque or optically anisotropic when viewed from above.

In one embodiment, interiors of the plurality of through holes are filled with the above-mentioned material having the optical isotropy.

In one embodiment, inner lateral surfaces of the plurality of through holes are coated with a light-shielding material.

In one embodiment, either or both of an upper surface and a lower surface of the optically isotropic region having the plurality of through holes are coated with the light-shielding material.

In one embodiment, the lower layer is an ultra thin glass (UTG) on which the thin film transistor is formed.

According to another aspect, a flexible display combined with an under-display sensor includes: a display layer comprising a thin film transistor driven by an applied electrical signal and a light emitting layer that generates light by means of the thin film transistor; a cover window including an optically clear flexible material to protect the display layer and laminated on the display layer; a flexible lower layer arranged below the display layer to support and protect the display layer and having optical isotropy; and the under-display sensor arranged below the lower layer to detect an intensity of polarized light passing through the lower layer.

In one embodiment, the lower layer includes: a polyimide (PI) layer, on which the thin film transistor is formed; a flexible base film arranged below the polyimide layer and having an optically isotropic region; and an optically clear adhesive component arranged between the polyimide layer and the base film.

In one embodiment, when viewed from above, the optically isotropic region is a part of the flexible base film, and the under-display sensor is arranged in the optically isotropic region.

In one embodiment, the under-display sensor includes: a light selection layer having a first light path and a second light path, wherein display circularly polarized light generated by external light incident from the outside and unpolarized light generated by pixels travel in the first light path and the second light path; and a light sensor having a first light receiving portion for detecting light passing through the first light path and a second light receiving portion for detecting light passing through the second light path.

In one embodiment, the first light path allows both the display circularly polarized light and the unpolarized light to pass. The second light path blocks the display circularly polarized light and allows the unpolarized light to pass.

In one embodiment, the light selection layer includes: a first sensor retarder layer; a first sensor polarizing layer forming the first light path below the first sensor retarder layer; and a second sensor polarizing layer forming the second light path below the first sensor retarder layer.

In one embodiment, the under-display sensor further includes a color filter layer. The color filter layer is arranged between the light selection layer and the light sensor, so that light passes through the first light path and the second light path depending on respective wavebands.

### BRIEF DESCRIPTION OF DRAWINGS

Embodiments of the present invention will be described below with reference to the accompanying drawings. To facilitate understanding, the same reference numerals are assigned to the same constituent elements throughout the specification. The structures shown in the drawings are merely exemplary embodiments for illustrating the present invention, but the scope of the present invention is not limited thereto. Particularly, in order to help the understanding of the present invention, some of the constituent elements are shown in a slightly exaggerated manner in the drawings. The drawings are means for helping the understanding of the present invention, and therefore, the widths, thicknesses, etc. of the constituent elements shown in the drawings may be different when actually embodied.

FIG. 1 is an exemplary diagram showing a path of light passing through a flexible display to be incident on an under-display sensor.

FIG. 2 is a diagram showing one example of a flexible display combined with an under-display sensor.

FIG. 3 is an exemplary diagram showing one embodiment of manufacturing the flexible display shown in FIG. 2.

FIG. 4 is an exemplary diagram showing another embodiment of manufacturing the flexible display shown in FIG. 2.

FIG. 5 is an exemplary diagram showing still another embodiment of manufacturing the flexible display shown in FIG. 2.

FIG. 6 is a diagram showing another example of a flexible display combined with an under-display sensor.

FIG. 7 is an exemplary diagram showing an embodiment of manufacturing the base film shown in FIG. 6.

FIG. 8 is a diagram showing yet another example of a flexible display combined with an under-display sensor.

FIG. 9 is an exemplary diagram showing an embodiment of manufacturing the flexible display shown in FIG. 8.

FIG. 10 is an exemplary diagram showing one embodiment of manufacturing the base film shown in FIG. 8.

FIG. 11 is a diagram showing an operation principle of the under-display sensor.

### DETAILED DESCRIPTION

The present invention is capable of being implemented in various ways to include various embodiments. Specific embodiments are illustrated in the drawings and described in detail. However, these are not intended to limit the present invention to the specific embodiments. The present invention includes all modifications, equivalents, or substitutes within the inventive concept and technical scope of the present invention. In particular, the functions, features, and embodiments described with reference to the drawings may be implemented independently or in combination with another embodiment. Therefore, the scope of the present invention is not limited to the manner shown in the drawings.

Further, the terms such as “substantially,” “almost,” and “about” used in this specification are expressions considering margins applied in actual implementation or errors that may occur. For example, “substantially 90 degrees” includes an angle that can be expected to achieve the same effect as 90 degrees. As another example, “almost absent” indicates an insignificant but negligible degree of presence included.

Furthermore, “lateral” or “horizontal” represents the left-right direction of the drawings, and “vertical” represents the up-down direction of the drawings, unless otherwise specified. In addition, an angle, an incident angle, etc. are based on an imaginary straight line perpendicular to the horizontal plane shown in the drawings, unless otherwise defined.

Throughout the drawings, the same reference numerals are used for the same or similar elements.

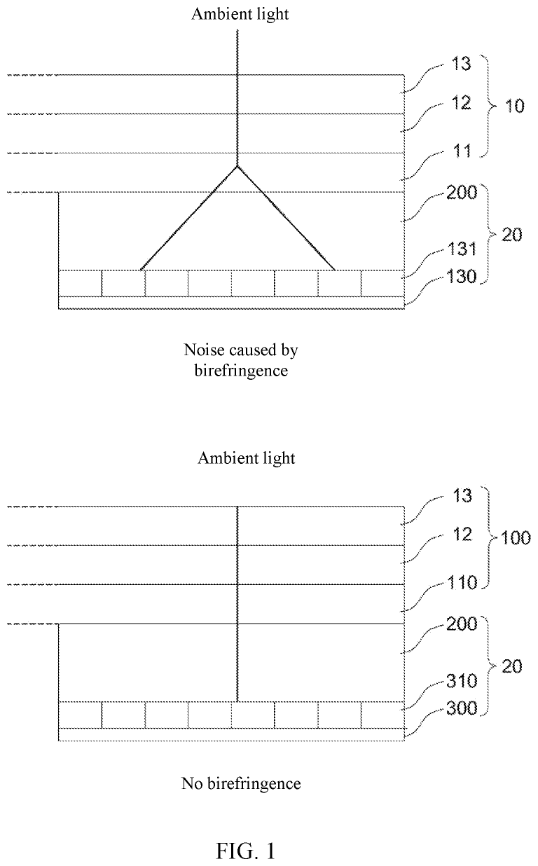

FIG. 1 is an exemplary diagram showing a path of light passing through a flexible display to be incident on an under-display sensor.

The flexible display 10 includes not only displays that are curved to have a certain curvature, but also foldable and rollable displays. The flexible display 10 includes a lower layer 11, a display layer 12, and a cover window 13. The display layer 12 also needs to have flexibility in order to restore the original state without being damaged even if the shape is changed by a physical force. In conventional rigid displays, a thin film transistor is formed on a carrier substrate, whereas in the flexible display 10, a thin film transistor is formed on a polyimide layer having excellent flexibility and heat resistance. The lower layer 11 includes a polyimide layer and a base film. The base film for protecting the very thin polyimide layer is attached to a lower surface of the polyimide layer. A representative material constituting the base film is polyethylene terephthalate (PET), which has anisotropy as an optical characteristic.

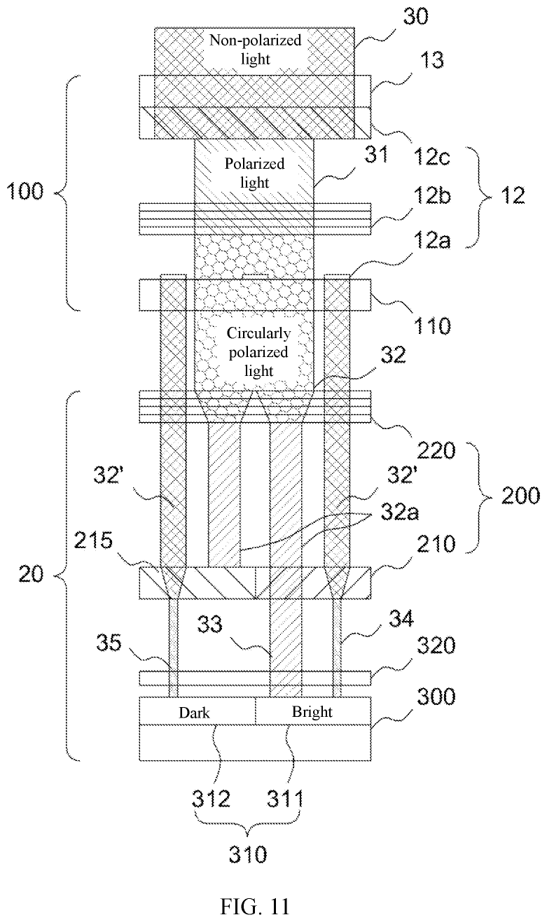

The under-display sensor 20 is arranged below the display 10 and receives polarized light that has passed through the display 10. The under-display sensor 20 includes a light sensor 300 and a light selection layer 200. The light sensor 300 includes a plurality of light receiving portions 310. A part of the plurality of light receiving portions receive display circularly polarized light (a first light path) incident from the display substantially without loss, but the remaining light receiving portions can hardly receive the display circularly polarized light (a second light path). The first path and the second path are defined by sensor polarizing layers (210, 215; FIG. 11) and a sensor retarder layer (220; FIG. 11) that constitute the light selection layer 200.

The lower layer 11 including the base film having optical anisotropy causes birefringence of the light emitted from the display layer 12. The display layer 12 includes a circularly polarizing layer that converts light incident from the outside into circularly polarized light. The circularly polarizing layer is functionally divided into a retarder layer and a polarizing layer. The external light is converted into display circularly polarized light by the circularly polarizing layer. When birefringence occurs, the refractive index changes according to the direction of a polarization axis. Therefore, the display circularly polarized light is refracted at different angles depending on the lower layer 11. Detailed description in this regard will be provided with reference to FIG. 11. The under-display sensor 20 detects a brightness, a proximity, or the like of external light by means of the intensity of light passing through the first light path and the second light path. Due to the birefringence, the same display circularly polarized light is detected by two or more light receiving portions 310 corresponding to the same light path, or detected by two or more light receiving portions 310 corresponding to different light paths. Therefore, the lower layer 11 having optical anisotropy has a profound impact on the operation of the under-display sensor 20.

In contrast, the lower layer 110 having optical isotropy substantially does not have an impact on the operation of the under-display sensor 20. The flexible display 100 includes a lower layer 110, a display layer 12 arranged on the lower layer 110, and a cover window 13 arranged on the display layer 12.

In the flexible display 100 including the lower layer 110 having optical isotropy, light incident on the under-display sensor 20 includes circularly polarized light from external light and unpolarized light generated at the display layer 12. The circularly polarized light and the unpolarized light pass through the lower layer 110 without birefringence. That is, in the lower layer 110, the incident position and the exit position of light are substantially located on the same vertical line. Accordingly, the light sensor 300 can detect the light passing through the clearly distinguished first light path and second light path.

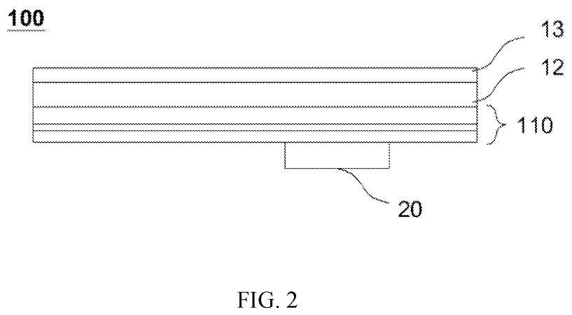

FIG. 2 is a diagram showing an example of a flexible display combined with an under-display sensor.

With reference to FIG. 2, the flexible display 100 includes a lower layer 110, a display layer 12, and a cover window 13. The under-display sensor 20 may be optically combined to a lower surface of the lower layer 110. Here, the under-display sensor 20 may be combined to a position that does not affect the shape deformation of the flexible display 100.

The lower layer 110 has optical isotropy and flexibility in its entirety. The lower layer 110 supports and protects the display layer 12. The lower layer 110 may include two or more laminated sub-layers. The sub-layers may include a polyimide layer 111 that functions as a substrate for a thin film transistor, an adhesive layer 112, and a base film 113. The adhesive layer 112 is an optically clear film such as an optically clear adhesive (OCA), and the polyimide layer 111 is fixed to the base film 113. The base film 113 is a flexible film having optical isotropy in its entirety.

The display layer 12 includes a thin film transistor driven by an applied electric signal and a light emitting layer that generates light by means of the thin film transistor. The display layer 12 generates light having different colors. Thus, the light emitting layer generates light of different wavelengths. The display layer 12 may further include a color filter that allows light of specific wavelengths to pass. On the other hand, the display layer 12 may further include a circularly polarizing layer and/or a touch sensor.

The cover window 13 is laminated on the display layer 12 to protect the display layer 12. The cover window 13 may be formed by an optically clear flexible material.

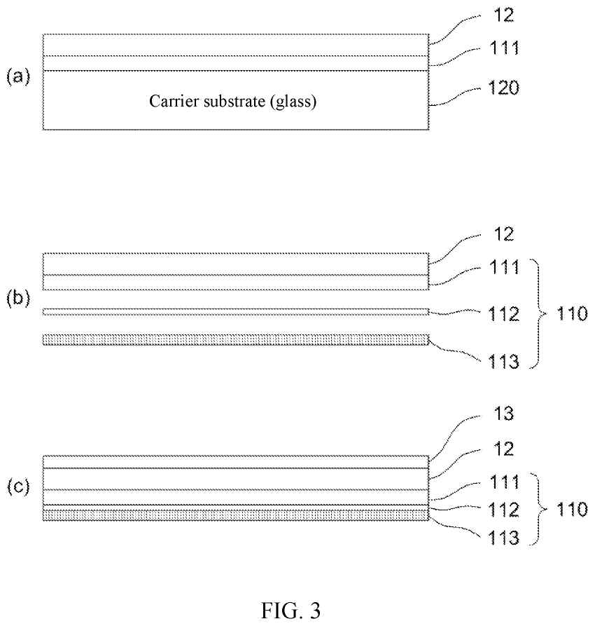

FIG. 3 is an exemplary diagram showing one embodiment of manufacturing the flexible display shown in FIG. 2.

In step (a), the polyimide layer 111 is formed on a carrier substrate 120, and a part of the display layer 12, such as a thin film transistor and a light emitting layer, is formed on the polyimide layer 111. The polyimide layer 111 is formed by, for example, coating the carrier substrate 120 with polyamic acid and then curing the same. The remaining parts of the display layer 12, such as a color filter, a circularly polarizing layer, and/or a touch sensor, are laminated in this step or the following steps.

In step (b), the polyimide layer 111 and a part of the display layer 12 are separated from the carrier substrate 120, and the base film 113 is attached to the lower surface of the polyimide layer 111. The adhesive layer 112 such as OCA or OCR (optically clear resin) is arranged between the polyimide layer 111 and the base film 113. The polyimide layer 111, the adhesive layer 112, and the base film 113 constitute the lower layer 110.

The base film 113 is formed by a flexible material having optical isotropy. The optically isotropic material is one or more selected from the group consisting of cellulose acetate propionate (CAP), ethylene vinylalcohol copolymer (EVOH), polyacrylate (PA), polyallylate (PAR), polycarbonate (PC), polyetherimide (PEI), polyethersulphone (PES), polyethylenenaphthalate (PEN), polyimide (PI), polymethylmethacrylate (PMMA), polyphenylene sulfide (PPS), polystyrene (PS), polyvinylidene chloride (PVDC), polyvinylidene difluoride (PVDF), styrene acrylonitrile (SAN), tri-acetyl cellulose (TAC), methylpentene (TPX), and combinations thereof.

In step (c), the remaining structural parts of the display layer 12 and the cover window 13 are laminated. The cover window 13 is formed by any one selected from the group consisting of cellulose acetate propionate (CAP), ethylene vinylalcohol copolymer (EVOH), polyacrylate (PA), polyallylate (PAR), polycarbonate (PC), polyetherimide (PEI), polyethersulphone (PES), polyethylenenaphthalate (PEN), polyimide (PI), polymethylmethacrylate (PMMA), polyphenylene sulfide (PPS), polystyrene (PS), polyvinylidene chloride (PVDC), polyvinylidene difluoride (PVDF), styrene acrylonitrile (SAN), tri-acetyl cellulose (TAC), methylpentene (TPX), and combinations thereof. Here, PI is CPI (Colorless PI). On the other hand, the cover window 13 is UTG (Ultra thin glass).

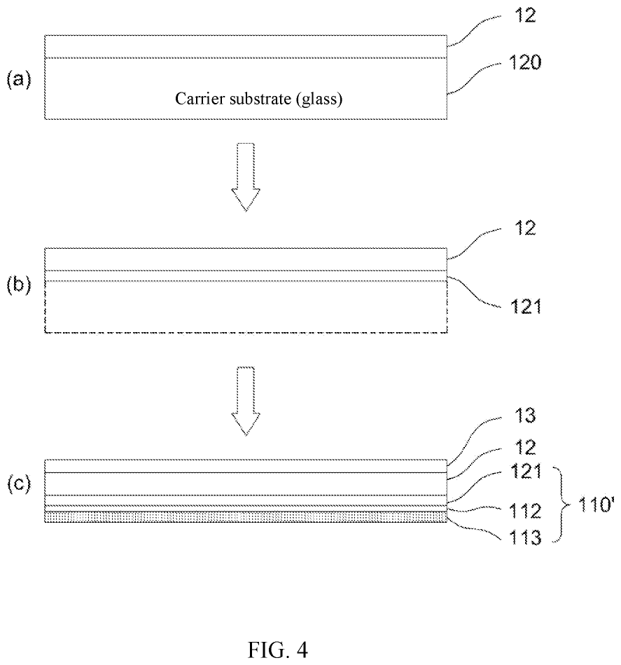

FIG. 4 is an exemplary diagram showing another embodiment of manufacturing the flexible display shown in FIG. 2. The same description as that with reference to FIG. 3 is omitted, and only the differences will be described.

In step (a), a part of the display layer 12, such as a thin film transistor and a light emitting layer, is formed on the carrier substrate 120. Alternatively, a polyimide layer 111 is formed on the carrier substrate 120, and a part of the display layer 12 is formed on the polyimide layer 111. The carrier substrate 120 is formed by an optically clear and optically isotropic material such as glass.

In step (b), backgrinding is performed on a lower surface of the carrier substrate 120 to form a very thin glass substrate 121. A thickness of the glass substrate 121 is about 100 μm or less, which is similar to the thickness of a commonly used ultra thin tempered glass. At this thickness, stress is small in the case of folding or curving. The lower layer 110′ has flexibility in its entirety.

In step (c), the remaining structural parts of the display layer 12 and the cover window 13 are laminated. Additionally or alternatively, a base film 113 for protecting the glass substrate 121 is attached to the lower surface of the glass substrate 121. The base film 113 is formed by a flexible material having optical isotropy. An adhesive layer 112 is arranged between the glass substrate 121 and the base film 113.

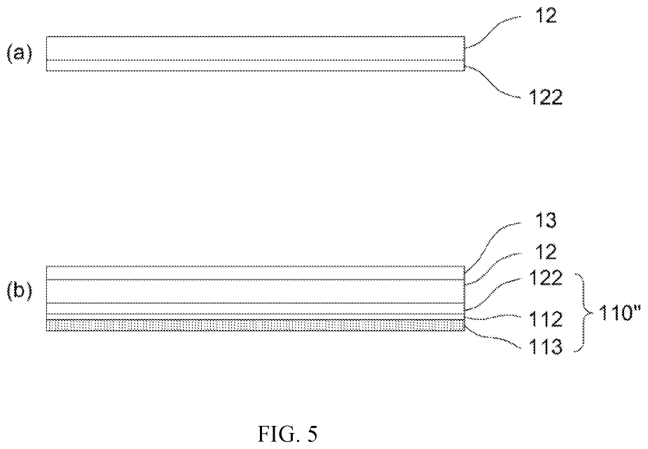

FIG. 5 is an exemplary diagram showing still another embodiment of manufacturing the flexible display shown in FIG. 2. The same descriptions as those with reference to FIGS. 2 and 3 are omitted, and only the differences will be described.

In step (a), a part of the display layer 12, such as a thin film transistor and a light emitting layer, is formed on an ultra thin tempered glass 122. Alternatively, a polyimide layer 111 is formed on the ultra thin tempered glass 122, and a part of the display layer 12 is formed on the polyimide layer 111.

The ultra thin tempered glass 122 may have a thickness of about 100 μm or less. At this thickness, stress is small in the case of folding or curving. The lower layer 110″ has flexibility in its entirety.

In step (b), the remaining structural parts of the display layer 12 and a cover window 13 are laminated. Additionally or alternatively, a base film 113 for protecting the ultra thin tempered glass 122 is attached to the lower surface of the ultra thin tempered glass 122. The base film 113 may be formed by a flexible material having optical isotropy. The adhesive layer 112 is arranged between the ultra thin tempered glass 122 and the base film 113.

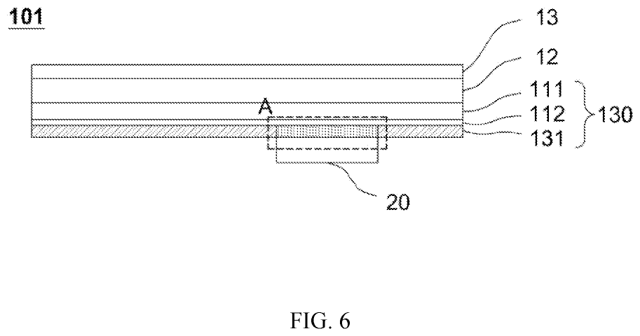

FIG. 6 is a diagram showing another example of a flexible display combined with an under-display sensor. The same description as that with reference to FIG. 2 is omitted, and only the differences will be described.

With reference to FIG. 6, a flexible display 101 includes a lower layer 130, a display layer 12, and a cover window 13. An under-display sensor 20 may be optically combined to the lower surface of the lower layer 110. Here, the under-display sensor 20 may be combined to a region A.

The lower layer 130 has flexibility in its entirety and partially has optical isotropy. The lower layer 130 may include two or more laminated sub-layers. The sub-layers may include a polyimide layer 111 that functions as a substrate for a thin film transistor, an adhesive layer 112, and a base film 131.

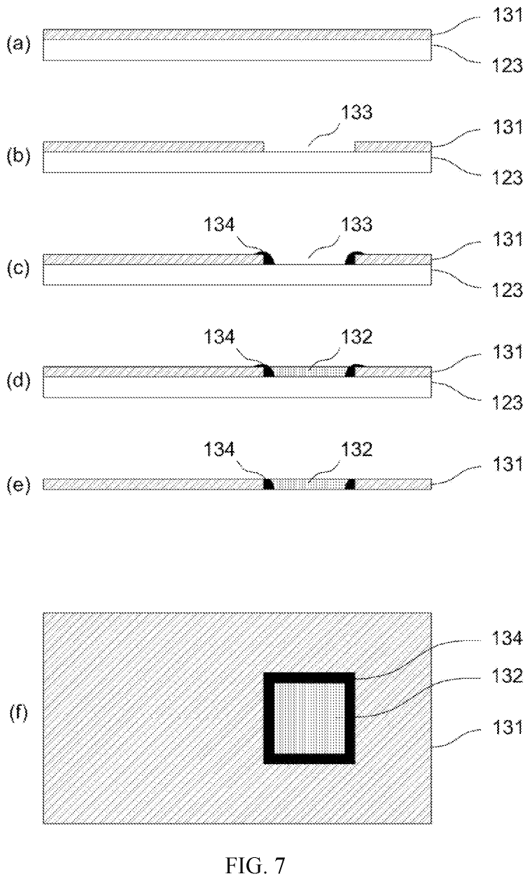

The base film 131 is a flexible film. When viewed from above, a part of the base film 131 is an optically isotropic region, and the remaining region of the base film 131 is an optically opaque region or an optically anisotropic region. The region A of the base film 131 is an optically isotropic region in its entirety. The base film 131 may have one or more optically isotropic regions. An embodiment of manufacturing the base film 131 having an optically isotropic region will be described in detail below with reference to FIG. 7.

The remaining region of the base film 131 may be optically opaque in whole or in part. As an embodiment, the base film 131 is prepared by mixing a light-shielding material such as brown pigment or carbon black in a liquid resin so as to be opaque in whole. On the other hand, the base film 131 may be coated with a light-shielding material on at least any one of the upper surface and the lower surface, and is thus opaque in whole. The base film 131, which is opaque in whole, can substantially block light to be incident on the under-display sensor. In another embodiment, the base film 131 may be partially optically opaque by coating at least any one of a part of the upper surface, a part of the lower surface, and an inner lateral surface with a light-shielding material. For example, the periphery of the optically isotropic region is locally coated with a light-shielding material. The partially optically opaque base film 131 can substantially block the incidence of light that is birefringent in the base film 131, which greatly reduces the amount of incident light.

FIG. 7 is an exemplary diagram showing an embodiment of manufacturing the base film shown in FIG. 6.

In step (a), a base film 131 is prepared. As an embodiment, the base film 131 may be prepared from a material having optical anisotropy. The material having optical anisotropy may be any one selected from the group consisting of ethylene tetrafluoroethylene (ETFE), chlorotrifluoroethylene (CTFE), polyetherimide (PEI), polyethersulphone (PES), polyethyeleneterepthalate (PET), polyphenylenesulfide (PPS), poly(aryleneether sulfone), poly(tetrafluoroethylene) (PTFE), and combinations thereof. In another embodiment, the base film 131 may be an opaque film manufactured by mixing light-shielding materials. To perform subsequent steps, the base film 131 may be arranged on a carrier substrate 123.

In step (b), a part of the base film 131 is removed to form a window 133 corresponding to an optically isotropic region 132.

In step (c), an optically opaque adhesive 134 is applied along an inner lateral surface of the window 133 so as to extend from the upper surface to the lower surface of the base film 131. The optically opaque adhesive 134 may include a light-shielding material. By applying the optically opaque adhesive 134, the area of the window 133 may be reduced slightly.

In step (d), the optically isotropic region 132 is formed within the window 133. In one embodiment, an optically isotropic film cut to have the same planar shape as the window 133 may be inserted into the window 133. In another embodiment, a liquid material having optical isotropy may be applied to the window 133. The liquid material is cured by heat or UV. The optically isotropic region 132 may be formed by any one selected from the group consisting of cellulose acetate propionate (CAP), ethylene vinylalcohol copolymer (EVOH), polyacrylate (PA), polyallylate (PAR), polycarbonate (PC), polyetherimide (PEI), polyethersulphone (PES), polyethylenenaphthalate (PEN), polyimide (PI), polymethylmethacrylate (PMMA), polyphenylene sulfide (PPS), polystyrene (PS), polyvinylidene chloride (PVDC), polyvinylidene difluoride (PVDF), styrene acrylonitrile (SAN), tri-acetyl cellulose (TAC), methylpentene (TPX), and combinations thereof.

In step (e), the optically opaque adhesive 134 remaining on the upper surface and/or the lower surface of the base film 131 is removed.

(f) shows the base film 131 described above. The optically isotropic region 132 is surrounded by the remaining region. The adhesive 134 is cured between the optically isotropic region 132 and the remaining region. The cured adhesive 134 prevents the birefringent light incident on the remaining region from entering the region 132.

Although not shown, in yet another embodiment, the application of the optically opaque adhesive 134 is omitted. When the optically isotropic film cut to have the same planar shape as the window 133 is inserted into the window 133, the base film 131 and the optically isotropic film may be joined by RF or laser. Either or both of the upper surface and lower surface of the periphery of the joint are coated with a light-shielding material.

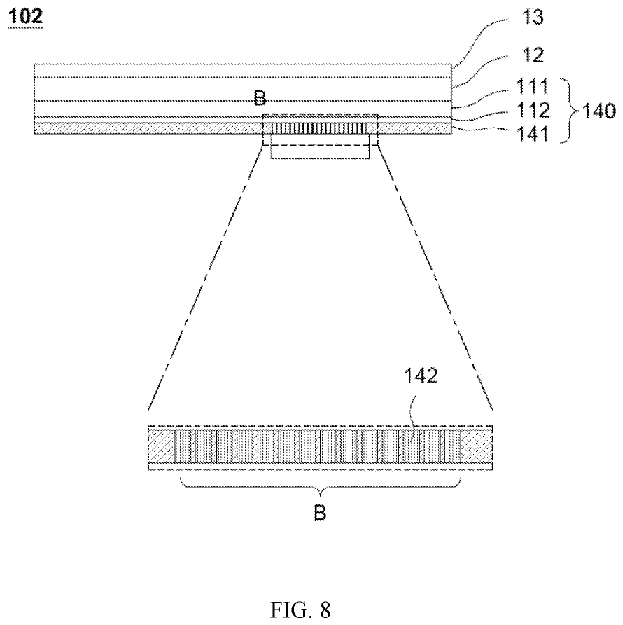

FIG. 8 is a diagram showing yet another example of a flexible display combined with an under-display sensor. The same description as that with reference to FIG. 6 is omitted, and only the differences will be described.

With reference to FIG. 8, a flexible display 102 includes a lower layer 140, a display layer 12, and a cover window 13. The under-display sensor 20 may be optically combined to the lower surface of the lower layer 140. Here, the under-display sensor 20 may be combined to a region B.

The lower layer 140 is flexible in its entirety and partially optically isotropic. The lower layer 140 may include two or more laminated sub-layers. The sub-layers may include a polyimide layer 111 that functions as a substrate for a thin film transistor, an adhesive layer 112, and a base film 141.

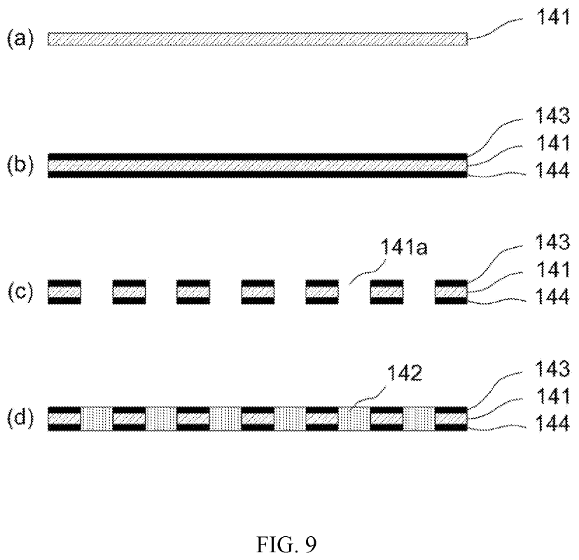

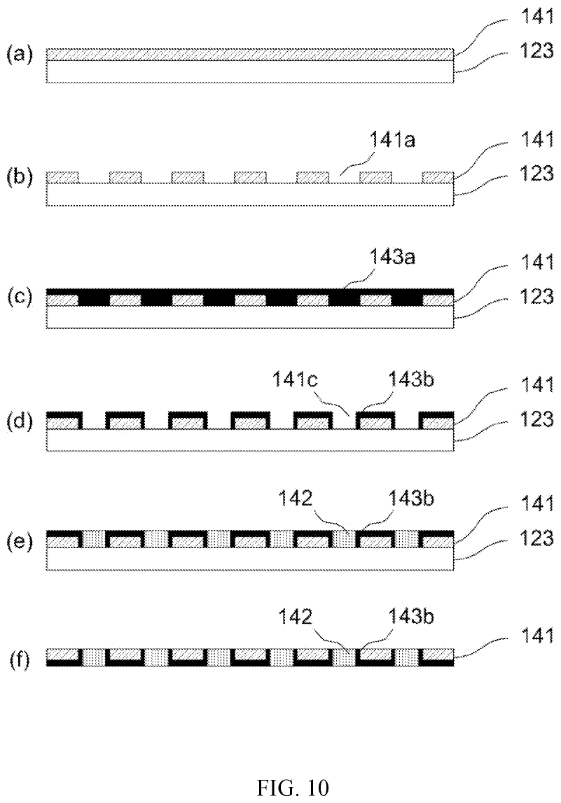

The base film 141 is a flexible film. When viewed from above, a part of the base film 141 is an optically isotropic region, and the remaining region of the base film 141 is an optically opaque region or an optically anisotropic region. The region B of the base film 141 is an optically isotropic region. The base film 141 may have one or more optically isotropic regions. An embodiment of manufacturing the base film 141 having an optically isotropic region will be described in detail below with reference to FIGS. 9 to 10.

The region B has local optical isotropy by a plurality of through holes. The plurality of through holes extend from the upper surface to the lower surface of the base film 141. In an embodiment, the base film 141 is an optically anisotropic film, and the interiors of the through holes may be filled with air or an optically isotropic material 142. The upper surface and/or lower surface of the region between the through holes may be coated with a light-shielding material. Additionally, inside walls of the through holes may be coated with a light-shielding material. In another embodiment, the base film 141 is an optically opaque film, and the interiors of the through holes may be filled with air or an optically isotropic material 142.

FIG. 9 is an exemplary diagram showing one embodiment of manufacturing the base film shown in FIG. 8 by enlarging the region B of FIG. 8.

In step (a), the base film 141 is prepared. The base film 141 may be prepared from a material having optical anisotropy. The material having optical anisotropy may be any one selected from the group consisting of ethylene tetrafluoroethylene (ETFE), chlorotrifluoroethylene (CTFE), polyetherimide (PEI), polyethersulphone (PES), polyethyeleneterepthalate (PET), polyphenylenesulfide (PPS), poly(aryleneether sulfone), poly(tetrafluoroethylene) (PTFE), and combinations thereof.

In step (b), the upper surface and/or the lower surface of the base film 141 are coated with a liquid light-shielding material. The applied light-shielding material is cured by heat or UV. In an embodiment, an upper coating 143 and a lower coating 144 may be formed only in the region B of FIG. 8. In another embodiment, the upper coating 143 and the lower coating 144 may be formed on the entire upper surface and/or the entire lower surface of the base film 141.

In step (c), a plurality of through holes 141a are formed in the region B. The plurality of through holes may be formed, for example, by perforating the coated base film 141 with laser.

In step (d), the plurality of through holes 141a are filled with an optically isotropic material 142. A liquid material having optical isotropy may be applied to the plurality of through holes 141a and then cured by heat or UV. The optically isotropic material 142 may be any one selected from the group consisting of cellulose acetate propionate (CAP), ethylene vinylalcohol copolymer (EVOH), polyacrylate (PA), polyallylate (PAR), polycarbonate (PC), polyetherimide (PEI), polyethersulphone (PES), polyethylenenaphthalate (PEN), polyimide (PI), polymethylmethacrylate (PMMA), polyphenylene sulfide (PPS), polystyrene (PS), polyvinylidene chloride (PVDC), polyvinylidene difluoride (PVDF), styrene acrylonitrile (SAN), tri-acetyl cellulose (TAC), methylpentene (TPX), and combinations thereof.

FIG. 10 is an exemplary diagram showing another embodiment of manufacturing the base film shown in FIG. 8 by enlarging the region B of FIG. 8. The same description as that with reference to FIG. 9 is omitted, and only the differences will be described. In addition, the embodiment described with reference to FIG. 10 may also be applied to the formation of the region A in FIG. 6.

In step (a), a base film 141 is prepared. The base film 141 may be prepared from a material having optical anisotropy. To perform subsequent steps, the base film 131 may be arranged on a carrier substrate 123.

In step (b), a plurality of through holes 141a are formed in the region B. The plurality of through holes may be formed, for example, by perforating the base film 141 with laser.

In step (c), the liquid light-shielding material 143a is applied to the region B. The applied light-shielding material fills the plurality of through holes 141a. In an embodiment, the light-shielding material fills the plurality of through holes 141a, and a layer may be formed in the region between the through holes. Then, the light-shielding material 143a is cured by heat or UV. In another embodiment, after the light-shielding material 143a filling the plurality of through holes 141a is cured by heat or UV (primary application and curing), the region B may be additionally coated with the applied light-shielding material 143a. The coated light-shielding material is cured or UV cured (secondary application and curing).

In step (d), a plurality of through holes 141c are formed in the region B. The through holes 141c may be formed by perforating the light-shielding material 143a filled in the through holes 141a with laser. After the perforation, a coating 143b formed by the light-shielding material remains on the inside walls of the through holes 141c and the region between the through holes.

In step (e), the plurality of through holes 141c are filled with the optically isotropic material 142. A liquid material having optical isotropy may be applied to the plurality of through holes 141c and then cured by heat or UV.

In step (f), the base film 141 is separated from the carrier substrate 123. The base film 141 is arranged so that the coating 143b formed in the region between the through holes faces the display layer 112 or arranged so as to face the opposite direction of the display layer 112.

FIG. 11 is a diagram showing an operation principle of the under-display sensor. The hatching lines shown in the retarder layer represent the direction of a slow axis, and the hatching lines shown in the polarizing layer schematically represent the direction of a polarization axis with respect to the slow axis extending in the horizontal direction. On the other hand, the slow axis of the display retarder layer and the slow axis of the sensor retarder layer both extend in the horizontal direction or the slow axis of the display retarder layer and the slow axis of the sensor retarder layer extend in the vertical direction. This is a simplified illustration for ease of understanding. The slow axis of the sensor retarder layer does not need to be aligned with the slow axis of the display retarder layer.

The under-display sensor 20 includes a light selection layer 200 and a light sensor 300. The light selection layer 200 includes a first sensor retarder layer 220, a first sensor polarizing layer 210, and a second sensor polarizing layer 215. The first sensor retarder layer 220 is arranged above the first sensor polarizing layer 210 and the second sensor polarizing layer 215, and the light sensor 300 is arranged below the first sensor polarizing layer 210 and the second sensor polarizing layer 215. The under-display color sensor may further include a color filter layer 320 arranged between the first sensor polarizing layer 210 and second sensor polarizing layer 215 and the light sensor 300 to define the waveband of the light incident on the light receiving portion 310. The light receiving portion 310 of the light sensor 300 is constituted by a first light receiving portion 311 and a second light receiving portion 312. The first light receiving portion 311 is arranged below the first sensor polarizing layer 210, and the second light receiving portion 312 is arranged below the second sensor polarizing layer 215. In an embodiment, the light selection layer 200 may be prepared by stacking (laminating) the first sensor retarder layer 220 on the upper surfaces of the first sensor polarizing layer 210 and the second sensor polarizing layer 215. The light selection layer 200 may be attached to the bottom surface of the display layer 12. The light sensor 300 may be attached to the bottom surface of the light selection layer 200. In another embodiment, the light sensor 300 may be implemented as a thin film transistor. Thus, the under-display sensor 20 may be produced by laminating the first sensor retarder layer 220, the first sensor polarizing layer 210, the second sensor polarizing layer 215, and the light sensor 300 in a film form.

The polarization axis of the first sensor polarizing layer 210 and the polarization axis of the second sensor polarizing layer 215 are inclined at different angles with respect to the slow axis of the first sensor retarder layer 220. The polarization axis of the first sensor polarizing layer 210 may be inclined at a first angle, such as +45 degrees, with respect to the slow axis of the first sensor retarder layer 220. The polarization axis of the second sensor polarizing layer 215 may be inclined at a second angle, such as −45 degrees, with respect to the slow axis of the first sensor retarder layer 220.

The first light receiving portion 311 of the light sensor 300 detects first sensor linearly polarized light 33 and second sensor linearly polarized light 34 from the first sensor polarizing layer 210. The second light receiving portion 312 detects third sensor linearly polarized light 35 from the second sensor polarizing layer 215. In the under-display illuminance sensor, the light receiving portion 310 may generate a pixel current having a magnitude corresponding to the amount of detected light. On the other hand, in the under-display illuminance sensor, the first sensor linearly polarized light 33, the second sensor linearly polarized light 34, and the third sensor linearly polarized light 35 pass through the color filter layer 320, so that the light receiving portion 310 may generate a pixel current having a magnitude corresponding to the amount of light in the respective wavebands. The light receiving portion 310 may be, for example, a photodiode, but is not limited thereto.

The color filter layer 320 is located between the light sensor 300 and the light selection layer 200. The color filter layer 320 is composed of, for example, red R, green G, blue B, and/or white W filters. Each color filter is located at a position substantially vertically above the first light receiving portion 311 or the second light receiving portion 312. The color filters allow light of specific wavebands to pass but block light that does not belong to the specific wavebands.

Next, the operation of the under-display sensor 20 having the light selection layer 200 of the above structure will be described.

The flexible display 100 includes a lower layer 110 having optical isotropy, a display layer 12, and a cover window 13. The display layer 12 includes a pixel layer 12a, a display retarder layer 12b, and a display polarizing layer 12c. The pixel layer 12a includes a thin film transistor and a light emitting layer. Here, the display retarder layer 12b and the display polarizing layer 12c are shown by functionally dividing the circularly polarizing layer. Similarly, the first sensor retarder layer 220, the first sensor polarizing layer 210, and the second sensor polarizing layer 215 are also shown by functionally dividing the circularly polarizing layer.

Display circularly polarized light 32 and unpolarized light 32′ are incident on the upper surface of the light selection layer 200, that is, the upper surface of the first sensor retarder layer 220. The display circularly polarized light 32 is light obtained from external light 30 passing through the display polarizing layer 12c and the display retarder layer 12b, and the unpolarized light 32′ is light traveling downward from the pixel layer 12a toward the light selection layer 200.

The display polarizing layer 12c may have a polarization axis inclined at a second angle, such as −45 degrees, with regard to the slow axis of the display retarder layer 12b. Accordingly, display linearly polarized light 31 passing through the display polarizing layer 12c may be incident at the second angle with respect to the slow axis of the display retarder layer 12b. When the first polarized light element of the display linearly polarized light 31 projected along the fast axis and the second polarized light element of the display linearly polarized light 31 projected along the slow axis pass through the display retarder layer 12b, a λ/4 phase difference is generated therebetween. As a result, the linearly polarized light 21 passing through the display retarder 12 can become the display circularly polarized light 32 that rotates counterclockwise.

The display circularly polarized light 32 having the phase difference of λ/4 between the fast axis and the slow axis passes through the first sensor retarder layer 220 and becomes sensor internal linearly polarized light 32a. The polarization axis of the sensor internal linearly polarized light 32a and the polarization axis of the display linearly polarized light 31 are orthogonal to each other. On the other hand, the unpolarized light 32′ passes through the first sensor retarder layer 220 as it is.

The polarization axis of the first sensor polarizing layer 210 is substantially parallel to the polarization axis of the sensor internal linearly polarized light 32a, so that the sensor internal linearly polarized light 32a from the first sensor retarder layer 220 can pass through the first sensor polarizing layer 210. In contrast, the polarization axis of the second sensor polarizing layer 215 is substantially perpendicular to the polarization axis of the sensor internal linearly polarized light 32a, so that the sensor internal linearly polarized light 32a can be blocked by the second sensor polarizing layer 215. On the other hand, the unpolarized light 32′ from the sensor retarder layer 220 passes through the first sensor polarizing layer 210 and the second sensor polarizing layer 215, respectively, to become second sensor linearly polarized light 34 and third sensor linearly polarized light 35. In the under-display color sensor, the first sensor linearly polarized light 33, the second sensor linearly polarized light 34, and the third sensor linearly polarized light 35 pass through the same type of color filter and then enter the light sensor 300. That is, the first light receiving portion 311 can detect the first sensor linearly polarized light 33 and the second sensor linearly polarized light 34 through the first light path composed of the first sensor retarder layer 220 and the first sensor polarizing layer 210, and the second light receiving portion 312 can detect the third sensor linearly polarized light 35 through the second light path composed of the first sensor retarder layer 220 and the second sensor polarizing layer 215.

While the disclosure includes a limited number of embodiments, those skilled in the art, having benefit of this disclosure, will appreciate that other embodiments may be devised which do not depart from the scope of the present disclosure. Accordingly, the scope should be limited only by the attached claims.

What is claimed is:

1. A flexible display suitable for an under-display sensor, comprising:
a display layer comprising a thin film transistor driven by an applied electric signal and a light emitting layer that generates light by means of the thin film transistor;
a cover window comprising an optically clear flexible material and laminated on the display layer to protect the display layer; and
a flexible lower layer arranged below the display layer to support and protect the display layer and having optical isotropy.

2. The flexible display according to claim 1, wherein the lower layer comprises:
a polyimide layer, on which the thin film transistor is formed;
a base film arranged below the polyimide layer and having the optical isotropy and flexibility; and
an optically clear adhesive component arranged between the polyimide layer and the base film.

3. The flexible display according to claim 2, wherein the base film is formed by any one selected from the group consisting of cellulose acetate propionate (CAP), ethylene vinylalcohol copolymer (EVOH), polyacrylate (PA), polyallylate (PAR), polycarbonate (PC), polyetherimide (PEI), polyethersulphone (PES), polyethylenenaphthalate (PEN), polyimide (PI), polymethylmethacrylate (PMMA), polyphenylene sulfide (PPS), polystyrene (PS), polyvinylidene chloride (PVDC), polyvinylidene difluoride (PVDF), styrene acrylonitrile (SAN), tri-acetyl cellulose (TAC), methylpentene (TPX), and combinations thereof.

4. The flexible display according to claim 2, wherein when viewed from above, a part of the base film is an optically isotropic region having the optical isotropy.

5. The flexible display according to claim 4, wherein the optically isotropic region is formed by any one selected from the group consisting of cellulose acetate propionate (CAP), ethylene vinylalcohol copolymer (EVOH), polyacrylate (PA), polyallylate (PAR), polycarbonate (PC), polyetherimide (PEI), polyethersulphone (PES), polyethylenenaphthalate (PEN), polyimide (PI), polymethylmethacrylate (PMMA), polyphenylene sulfide (PPS), polystyrene (PS), polyvinylidene chloride (PVDC), polyvinylidene difluoride (PVDF), styrene acrylonitrile (SAN), tri-acetyl cellulose (TAC), methylpentene (TPX), and combinations thereof.

6. The flexible display according to claim 4, wherein a remaining region of the base film is optically opaque or optically anisotropic when viewed from above.

7. The flexible display according to claim 6, wherein the remaining region is formed by any one selected from the group consisting of ethylene tetrafluoroethylene (ETFE), chlorotrifluoroethylene (CTFE), polyetherimide (PEI), polyethersulphone (PES), polyethyeleneterepthalate (PET), polyphenylenesulfide (PPS), poly(aryleneether sulfone), poly(tetrafluoroethylene) (PTFE), and combinations thereof.

8. The flexible display according to claim 4, wherein the base film further comprises a light-shielding region arranged between the optically isotropic region and the remaining region of the base film and extending from an upper surface of the base film to a lower surface of the base film.

9. The flexible display according to claim 2,
wherein an optically isotropic region of the base film comprises a plurality of through holes extending from an upper surface to a lower surface, and
wherein a remaining region of the base film is optically opaque or optically anisotropic when viewed from above.

10. The flexible display according to claim 9, wherein interiors of the plurality of through holes are filled with a material having the optical isotropy.

11. The flexible display according to claim 9, wherein inner lateral surfaces of the plurality of through holes are coated with a light-shielding material.

12. The flexible display according to claim 9, wherein either or both of the upper surface and the lower surface of the optically isotropic region having the plurality of through holes are coated with a light-shielding material.

13. The flexible display according to claim 1, wherein the lower layer is an ultra thin glass (UTG) on which the thin film transistor is formed.

14. A flexible display combined with an under-display sensor, comprising:
a display layer comprising a thin film transistor driven by an applied electrical signal and a light emitting layer that generates light by means of the thin film transistor;
a cover window comprising an optically clear flexible material and laminated on the display layer to protect the display layer;
a flexible lower layer arranged below the display layer to support and protect the display layer and having optical isotropy; and
the under-display sensor arranged below the lower layer to detect an intensity of polarized light passing through the lower layer.

15. The flexible display combined with an under-display sensor according to claim 14, wherein the lower layer comprises:
a polyimide layer, on which the thin film transistor is formed;
a flexible base film arranged below the polyimide layer and having an optically isotropic region; and
an optically clear adhesive component arranged between the polyimide layer and the base film.

16. The flexible display combined with an under-display sensor according to claim 15, wherein when viewed from above, the optically isotropic region is a part of the flexible base film, and wherein the under-display sensor is arranged in the optically isotropic region.

17. The flexible display combined with an under-display sensor according to claim 14, wherein the under-display sensor comprises:
a light selection layer having a first light path and a second light path, wherein display circularly polarized light generated by external light incident from the outside and unpolarized light generated by pixels travel in the first light path and the second light path; and
a light sensor having a first light receiving portion for detecting light passing through the first light path and a second light receiving portion for detecting light passing through the second light path.

18. The flexible display combined with an under-display sensor according to claim 17,
wherein the first light path allows both the display circularly polarized light and the unpolarized light to pass, and
wherein the second light path blocks the display circularly polarized light and allows the unpolarized light to pass.

19. The flexible display combined with an under-display sensor according to claim 17, wherein the light selection layer comprises:
a first sensor retarder layer;
a first sensor polarizing layer forming the first light path below the first sensor retarder layer; and
a second sensor polarizing layer forming the second light path below the first sensor retarder layer.

20. The flexible display combined with an under-display sensor according to claim 17, wherein the under-display sensor further comprises a color filter layer arranged between the light selection layer and the light sensor, so that light passing through the first light path and the second light path passes depending on respective wavebands.
